(19) United States
(12) Patent Application Publication
(10) Pub. No.: US 2015/0028940 A1
(43) Pub. Date: Jan. 29, 2015

(54) INTEGRATED CIRCUIT HAVING AT LEAST ONE FUNCTIONAL CIRCUIT BLOCK OPERATING IN MULTI-SOURCE POWER DOMAIN AND RELATED SYSTEM WITH POWER MANAGEMENT

(71) Applicant: MEDIATEK INC., Hsin-Chu (TW)

(72) Inventors: You-Ming Tsao, Taipei City (TW); Kin Lam Tong, MACAU (MO); Chun-Fang Peng, Hsinchu City (TW)

(21) Appl. No.: 14/325,284

(22) Filed: Jul. 7, 2014

Related U.S. Application Data
(60) Provisional application No. 61/858,744, filed on Jul. 26, 2013.

(51) Int. Cl. G05F 1/66; H01L 27/02

(52) U.S. Cl. CPC G05F 1/66; H01L 27/0203
USPC 327/538; 327/565

(57) ABSTRACT

An integrated circuit has a semiconductor layer, at least one metal layer, a plurality of functional circuit blocks formed on the semiconductor layer, and a power mesh formed on the at least one metal layer. The power mesh has a specific area corresponding to a specific functional circuit block of the functional circuit blocks. The specific area at least has a first power trunk of a first power source and a second power trunk of a second power source distributed therein.

### CROSS REFERENCE TO RELATED APPLICATIONS

This application claims the benefit of U.S. provisional application No. 61/858,744, filed on Jul. 26, 2013 and incorporated herein by reference.

### BACKGROUND

The disclosed embodiments of the present invention relate to an integrated circuit design, and more particularly, to an integrated circuit having at least one functional circuit block operating in a multi-source power domain and a related system with power management.

Leakage current is the unintended loss of electrical current. A semiconductor device (e.g., an integrated circuit or chip) makes use of millions of transistors to perform designated functions, where the transistors are circuit elements used to amplify and switch electrical signals. Hence, the leakage current of the semiconductor device almost occurs at the transistor level. As semiconductor manufacturers continue to make transistors smaller to squeeze more into a single chip, the total amount of leakage current becomes larger due to the fact that smaller transistors have thinner insulating layers, causing more leakage current. Further, even though an improved semiconductor process may be adopted to reduce leakage of a single transistor, the total leakage of a larger chip is still high due to more transistors integrated in the same chip.

The leakage in transistors causes the semiconductor device to require more power to operate normally. As a result, the standby time of a mobile device powered by a battery device will be shorter when the leakage current increases.

One conventional design uses an on-chip power switch approach to solve the leakage issue. For example, one power domain is partitioned into a plurality of power switch domains each controlled by one power switch such as a multi-threshold complementary metal-oxide semiconductor (MTCMOS). When a power switch of a power switch domain is switched on, a power source is electrically connected to circuit components inside the power switch domain to provide a supply voltage to each of the circuit components; and when the power switch of the power switch domain is switched off, the power source is disconnected from the circuit components inside the power switch domain, thus powering off each of the circuit components for leakage reduction. However, there are still a lot of always-on feedthrough buffers inserted in the power switch domain that cannot be powered off. The number of feedthrough buffers will increase when the chip complexity increases. Further, the power switch itself will also cause leakage.

### SUMMARY

In accordance with exemplary embodiments of the present invention, an integrated circuit having at least one functional circuit block operating in a multi-source power domain and a related system with power management are proposed to solve the above-mentioned problem.

According to a first aspect of the present invention, an exemplary integrated circuit is disclosed. The exemplary integrated circuit includes a semiconductor layer, at least one metal layer, a plurality of functional circuit blocks formed on the semiconductor layer, and a power mesh formed on the at least one metal layer. The power mesh has a specific area corresponding to a specific functional circuit block of the functional circuit blocks, the specific area at least has a first power trunk of a first power source and a second power trunk of a second power source distributed therein.

According to a second aspect of the present invention, an exemplary system with power management is disclosed. The system includes a first integrated circuit and a second integrated circuit. The first integrated circuit includes at least a first power source and a second power source. The second integrated circuit is externally coupled to the first integrated circuit, and has at least one functional circuit block. The functional circuit block has at least one first power-domain block powered by the first power source and at least one second power-domain block powered by the second power source. The first integrated circuit enables the first power source and the second power source when the second integrated circuit is in a normal mode, and disables the first power source and enables the second power source when the second integrated circuit is in a suspend mode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a simplified cross-sectional view of an integrated circuit according to an embodiment of the present invention.

FIG. 2 is a diagram illustrating a partial configuration of the power mesh in a specific area of the metal layer.

FIG. 3 is a diagram illustrating a specific functional circuit block to which the specific area of the metal layer corresponds.

FIG. 4 is a diagram illustrating a system using a multi-bulk solution according to an embodiment of the present invention.

FIG. 5-FIG. 14 are diagrams illustrating different exemplary connection designs between an output port of a source end and an input port of a destination end, respectively.

FIG. 15 is a diagram illustrating a system using a single-bulk solution according to an embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

The key idea of the present invention is to use multi-source power domain architecture for leakage reduction. With the use of distributed multi-source power domain architecture, the placement of circuit components powered by different power sources is more flexible, which may lead to a reduced number of feedthrough buffers needed. Besides, when power sources used by an integrated circuit are controlled by external power sources, power switches in a multi-source power domain architecture are allowed to be powered off, thus further reducing the leakage caused by power switches. In addition, certain feedthrough buffers may be powered by a power source that can be shut down. This may further reduce the leakage for power saving when the feedthrough buffers are powered off by the shut-down power source. Further details of the proposed multi-source power domain architecture are described as below.

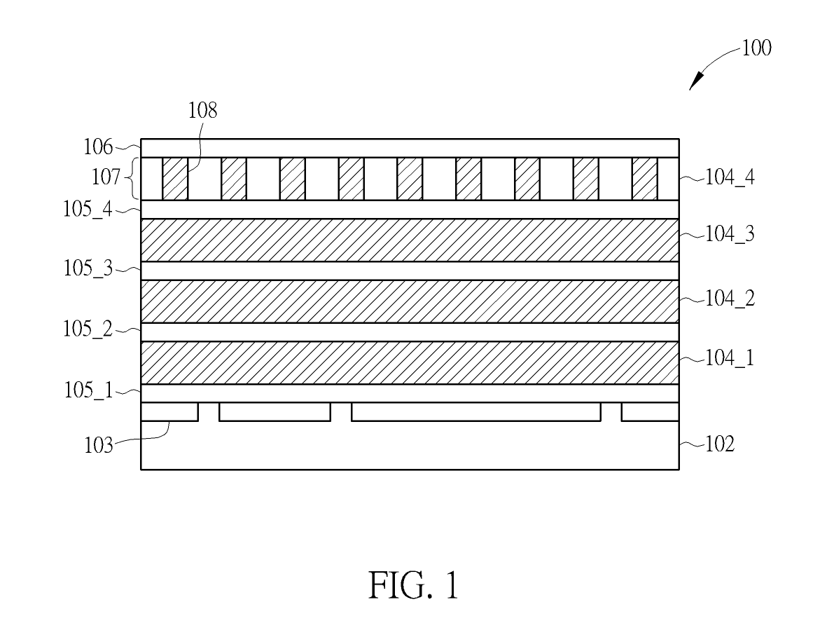

FIG. 1 is a simplified cross-sectional view of an integrated circuit according to an embodiment of the present invention. An integrated circuit (i.e., a semiconductor chip) 100 may include a semiconductor layer 102, a plurality of metal layers (e.g., 104_1, 104_2, 104_3 and 104_4), a plurality of insulating layers (e.g., 105_1, 105_2, 105_3 and 105_4), and a passivation layer 106. The semiconductor layer 102, which may be polysilicon, may be used for forming transistors and other electronic devices and may also be used for routing some of the electrical connections between these devices. Specifically, the integrated circuit 100 may have a plurality of functional circuit blocks 103 formed on the semiconductor layer 102. However, wire routing occupies space on the semiconductor layer 102 which otherwise could be used for the electronic devices. As a result, only the shorter electrical connections are formed on the semiconductor layer 102. For the remainder of the electrical connections, metal layers above the semiconductor layer 102 may be used. For example, metal layers 104_1-104_3 may be used for wire routing of longer electrical connections. By routing wires in the metal layers 104_1-104_3, electrical connections can be made without using valuable space on the semiconductor layer 102.

Besides, a power mesh 107 composed of a plurality of power trunks 108 may be formed on at least one metal layer (e.g., metal layer 104_1, 104_2, 104_3 and/or 104_4 in this example), where the power mesh 107 is part of a power distribution network, and is used for transmitting the required supply voltages to the functional circuit blocks 103. As shown in FIG. 1, one insulating layer 105_1 is between the semiconductor layer 102 and the metal layer 104_1, one insulating layer 105_2 is between metal layers 104_1 and 104_2, one insulating layer 105_3 is between metal layers 104_2 and 104_3, and one insulating layer 105_4 is between the metal layers 104_3 and 104_4. For example, each of the insulating layers 105_1-105_4 may be an oxide film. Connections between any of the metal layers 104_1-104_4 and the semiconductor layer 102 may be made using interlayer conductive holds called vias (not shown). The passivation layer 106 may be used to avoid the deterioration of the electrical properties of the integrated circuit 100 caused by water and other external contaminants.

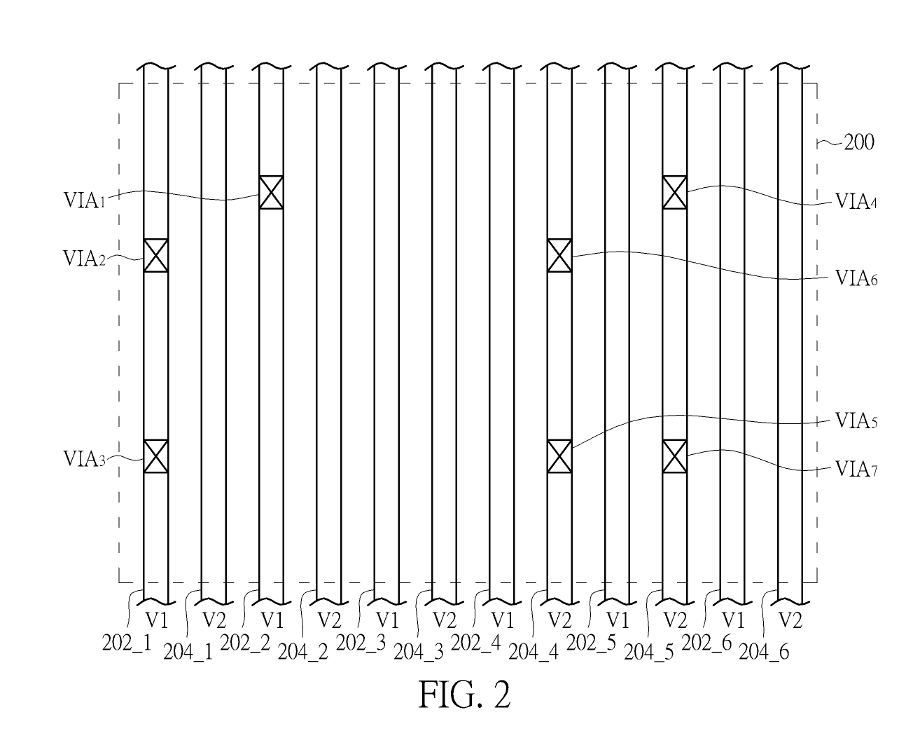

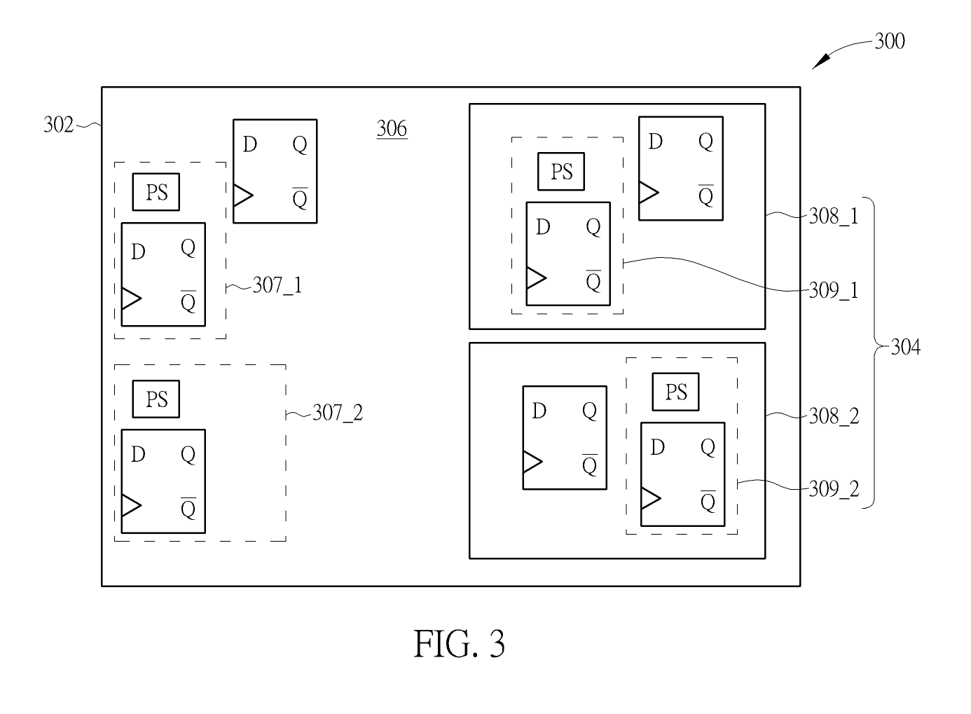

In this embodiment, the power mesh 107 is properly designed such that at least one of the functional circuit blocks 103 is operated in a multi-source power domain. Please refer to FIG. 2 in conjunction with FIG. 3. FIG. 2 is a diagram illustrating a partial configuration of the power mesh 107 in a specific area 200 of the metal layer 104_4 shown in FIG. 1. FIG. 3 is a diagram illustrating a specific functional circuit block 300 to which the specific area 200 of the metal layer 104_4 corresponds. The specific area 200 may include at least one or more first power trunks 202_1-202_6 of a first power source V1 and one or more second power trunks 204_1-204_6 of a second power source V2 distributed therein. The first power source V1 and the second power source V2 can be of the same voltage or different voltages.

In accordance with the proposed multi-source power domain architecture, the first power trunks 202_1-202_6 and the second power trunks 204_1-204_6 of different power sources V1 and V2 are distributed in the same specific area 200. Therefore, the power sources V1 and V2 can be accessed at multiple locations or even any location in the specific area 200. Thus instead of being grouped together, the circuit cells/blocks powered by the same power source can be positioned at different locations since they can access the power source at different locations. The distributed multiple power sources in the same specific area allow higher circuit design freedom. Besides, the cells/blocks that really need to be always-on can be coupled to the same power source, so that the other power source can be shut off as necessary to further save power. For clarity and simplicity, the following takes an interleaving configuration as an example of the multi-source power trunk distribution. Hence, the first power trunks 202_1-202_6 and the second power trunks 204_1-204_6 may be arranged in the specific area 200 in an interleaving fashion, as shown in FIG. 2. In this example, the first power trunks 202_1-202_6 may be uniformly distributed in the specific area 200, and the second power trunks 204_1-204_6 may be uniformly distributed in the specific area 200. That is, 50% of power trunks placed in the specific area 200 may be first power trunks of the first power source V1, and 50% of power trunks placed in the specific area 200 may be second power trunks of the second power source V2. However, this is for illustrative purposes only, and is not meant to be a limitation of the present invention. In other words, the interleaving configuration of power trunks of multiple power sources may be adjusted, depending upon actual design consideration. In one alternative interleaving design, M% of power trunks placed in the specific area 200 may be first power trunks of the first power source V1, and N% of power trunks placed in the specific area 200 may be second power trunks of the second power source V2, where M>N. For example, M=80 and N=20. Hence, if the power trunks are uniformly distributed, four first power trunks may be disposed between two second power trunks, and one second power trunk may be disposed between two first power trunks. In another alternative interleaving design, I% of power trunks placed in the specific area 200 may be first power trunks of the first power source V1, and J% of power trunks placed in the specific area 200 may be second power trunks of the second power source V2, where I<J. For example, I=20 and J=80. Hence, if the power trunks are uniformly distributed, four second power trunks may be disposed between two first power trunks, and one first power trunk may be disposed between two second power trunks.

By way of example, but not limitation, the specific functional circuit block 300 of the functional circuit blocks 103 in the integrated circuit 100 may be a modem subsystem used for wireless communication. In this example, the specific functional circuit block 300 may include a first power-domain block 302 and a second power-domain block 304, where the first power-domain block 302 may be coupled to at least one of the first power trunks 202_1-202_6 (i.e., the first power-domain block 302 may be powered by the first power source V1), and the second power-domain block 304 may be coupled to at least one of the second power trunks 204_1-204_6 (i.e., the second power-domain block 304 may be powered by the second power source V2). In this example, the first power-domain block 302 may include one always-on block 306 and two power-switchable blocks 307_1, 307_2, where the always-on block 306 may be a circuit block with no power switch PS designed to control the power supply of internal circuit components, and each of the power-switchable blocks 307_1, 307_2 may be a circuit block having a power switch PS designed to control the power supply of internal circuit components. The second power-domain block 304 may include two always-on blocks 308_1, 308_2 and two power-switchable blocks 309_1, 309_2, where each of the always-on blocks 308_1, 308_2 may be a circuit block with no power switch PS designed to control the power supply of internal circuit components, and each of the power-switchable blocks 309_1, 309_2 may be a circuit block having a power switch PS designed to control the power supply of internal circuit components.

It should be noted that, besides meaning real always-on, the term “always-on” used in the present invention may also mean “no power switch”. When there is no power switch in the always-on block, the on/off state of the always-on block depends on the on/off state of a power source to which the always-on block couples. For example, one always-on block may be powered off if it is connected to a power trunk of a power source (e.g., V1) that can be shut down, and another always-on block may be always active if it is connected to a power trunk of a power source (e.g., V2) that is not allowed to be shut down. Therefore, if a circuit block with no power switch is required to be always active, i.e., a real always-on block, it should be configured to drain the supply voltage from a power source (e.g., V2) that is not allowed to be shut down.

As the specific area 200 of the power mesh 107 corresponding to the specific functional circuit block 300 may have power trunks of multiple power sources distributed therein, the placement of circuit components belonging to different power domains is more flexible when compared to the conventional design, which leads to a reduced number of feedthrough buffers needed. As can be seen from FIG. 2 and FIG. 3, the always-on block 306 may be powered by the first power source V1 through at least the via VIA₁ and the first power trunk 202_2, the power-switchable block 307_1 may be powered by the first power source V1 through at least the internal power switch PS, the via VIA₂ and the first power trunk 202_1, and the power-switchable block 307_2 may be powered by the first power source V1 through at least the internal power switch PS, the via VIA₃ and the first power trunk 202_1. Similarly, the always-on block 308_1 may be powered by the second power source V2 through at least the via VIA₄ and the second power trunk 204_5, the always-on block 308_2 may be powered by the second power source V2 through at least the via VIA₅ and the second power trunk 204_4, the power-switchable block 309_1 may be powered by the second power source V2 through at least the internal power switch PS, the via VIA₆ and the second power trunk 204_4, and the power-switchable block 309_2 may be powered by the second power source V2 through at least the internal power switch PS, the via VIA₇ and the second power trunk 204_5.

As shown in FIG. 2 and FIG. 3, each of the power sources V1 and V2 is coupled to at least one always-on block and at least one power-switchable block. However, this is for illustrative purposes only, and is not meant to be a limitation of the present invention. There can be no always-on block or power-switchable block coupled to the power sources V1 or V2. Any power mesh design having the proposed multi-source power domain architecture (i.e., power trunks of different power sources distributed in the same area corresponding to one functional circuit block) falls within the scope of the present invention.

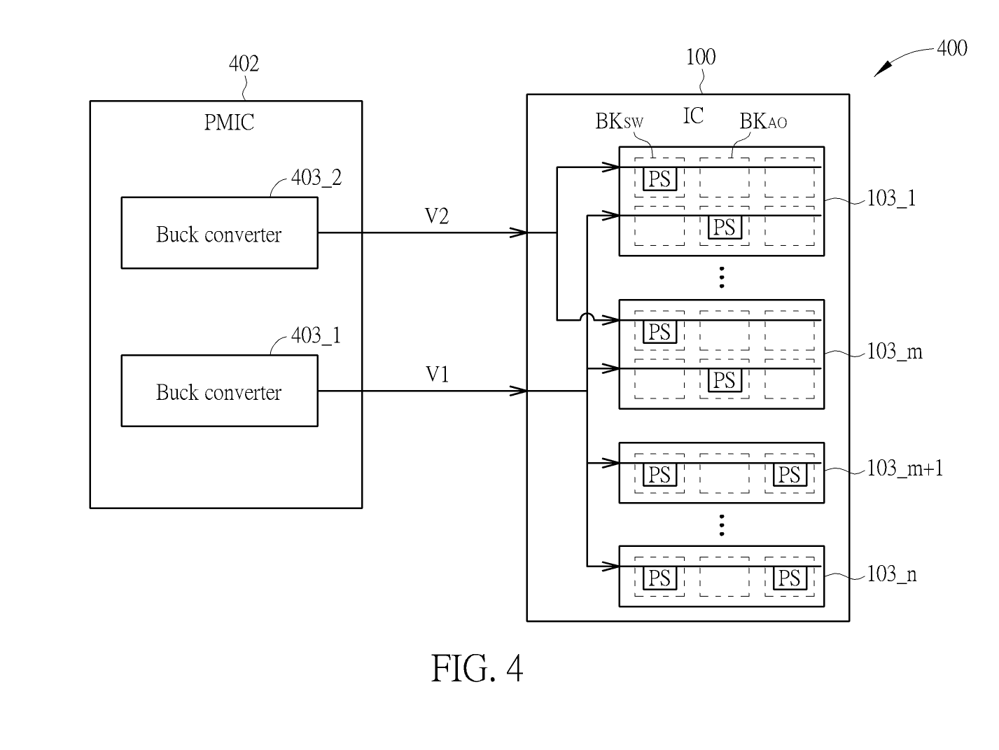

In a case where a first power source design proposed by the present invention is employed, the first power source V1 and the second power source V2 used by the integrated circuit 100 may be derived from external power sources of the integrated circuit 100, respectively. Please refer to FIG. 4, which is a diagram illustrating a system using a multi-bulk solution according to an embodiment of the present invention. By way of example, but not limitation, the system 400 may be a mobile phone chipset. As shown in FIG. 4, the system 400 may include a power management integrated circuit (PMIC) 402 and the aforementioned integrated circuit (IC) 100. The PMIC 402 may have multiple buck converters for generating multiple supply voltages. In this example, the PMIC 402 has buck converters 403_1 and 403_2 acting as external power sources of the integrated circuit 100, where the first power source V1 in the integrated circuit 100 can be derived from the buck converter 403_1 of the external PMIC 402, and the second power source V2 in the integrated circuit 100 can be derived from the buck converter 403_2 of the external PMIC 402. The first power source V1 and the second power source V2 can be of the same voltage or different voltages.

In this embodiment, the integrated circuit 100 may have a plurality of functional circuit blocks 103_1-103_n, where each of the functional circuit blocks 103_1-103_m may be operated in a multi-source power domain proposed by the present invention, and each of the functional circuit blocks 103_m+1-103_n may be operated in a conventional single-source power domain. Besides, each of the functional circuit blocks 103_1-103_n may include at least one always-on block BK_{AO} and/or at least one power-switchable block BK_{SW}. The power-switchable block BK_{SW} can be powered off by controlling the associated power switch. To reduce more leakage, the present invention proposes shutting off certain external power source(s) and only keeping external power source(s) of real always-on power domain(s) active when the system 400 enters a standby/suspend/power-saving mode. Specifically, when system 400 operates normally (i.e., the integrated circuit 100 is in a normal mode), the PMIC 402 may enable both of the first power source V1 and the second power source V2 (i.e., the buck converters 403_1, 403_2 are both active). However, when the system 400 enters a standby/suspend/power-saving mode (i.e., the integrated circuit 100 is in a standby/suspend/power-saving mode), the first power source V1 maybe shut off due to the inactivated buck converter 403_1, and the second power source V2 may remain active due to the buck converter 403_2 which is still active. In this way, the first power-domain blocks coupled to the first power source V1 in the functional circuit blocks 103_1-103_n maybe all powered off. As all of the power switches in the first power-domain blocks can be powered off, the leakage reduction is enhanced correspondingly.

In one exemplary design, the always-on block 306 in the V1 power domain may be a source end configured to generate an output to a destination end that may be the power-switchable block 307_1/307_2 in the V1 power domain, the always-on block 308_1/308_2 in the V2 power domain, or the power-switchable block 309_1/309_2 in the V2 power domain. In another exemplary design, power-switchable block 307_1/307_2 in the V1 power domain may be a source end configured to generate an output to a destination end that may be the always-on block 306 in the V1 power domain, the always-on block 308_1/308_2 in the V2 power domain, or the power-switchable block 309_1/309_2 in the V2 power domain. In another exemplary design, the always-on block 308_1/308_2 in the V2 power domain may be a source end configured to generate an output to a destination end that may be the always-on block 306 in the V1 power domain, the power-switchable block 307_1/307_2 in the V1 power domain, or the power-switchable block 309_1/309_2 in the V2 power domain. In another exemplary design, the power-switchable block 309_1/309_2 in the V2 power domain may be a source end configured to generate an output to a destination end that may be the always-on block 306 in the V1 power domain, the power-switchable block 307_1/307_2 in the V1 power domain, or the always-on block 308_1/308_2 in the V2 power domain. Special cells, such as level shifters, isolation cells, enable level shifters, etc., may be placed between different power domains or blocks to ensure normal functionality of the circuit design. The level shifter may be arranged to handle multi-voltage designs. More specifically, when driving signals between power domains with radically different power rails, a level shifter may be needed to shift a signal that comes in at one voltage level to an output that is at a different voltage level. Level shifters do not affect the functionality of the circuit design since they are just buffers from a logical perspective. Isolation cells may be used to prevent short circuit current, and should not be powered off. The isolation cell may be regarded as an OR gate or an AND gate from a logical perspective. The enable level shifter may be regarded as a combination of one level shifter and one isolation cell from a logical perspective. However, the physical circuit architecture of the special cell may vary, depending upon actual design consideration.

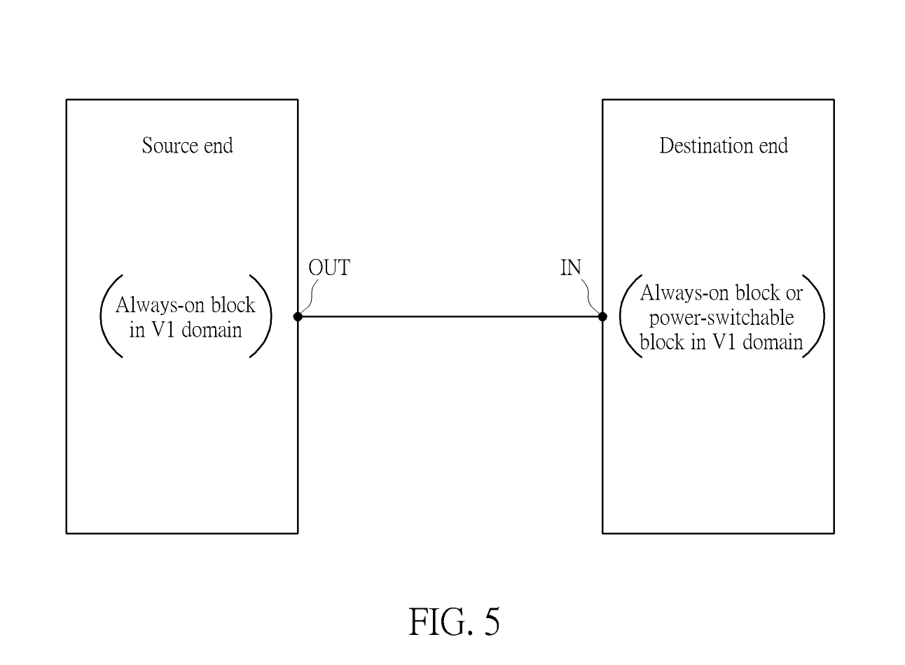

Suppose that the first power source V1 and the second power source V2 provide different supply voltages (e.g., 1.05V and 1.1V), and the first power source V1 is shut off when a standby/suspend/power-saving mode is enabled. Please note that, in other embodiments, the first power source V1 and the second power source V2 may provide the same or different supply voltages. In contrast to the convention low power design that controls power switches to power off circuit components in the corresponding power switch domains, the present invention proposes shutting off an external power source (e.g., the buck converter 403_1 in the PMIC 402) to power off all circuit components, including power switches, in a corresponding power domain. Hence, the design rules for placing the special cells, such as level shifters, isolation cells, enable level shifters, etc., should be properly set to ensure the normal functionality of the circuit design. Please refer to FIG. 5-FIG. 14, which are diagrams illustrating different exemplary connection designs between an output port OUT of a source end and an input port IN of a destination end, respectively. It should be noted that, for clarity and simplicity, FIG. 5-FIG. 14 only illustrate the design rule of special cells, such as level shifters, isolation cells, enable level shifters, etc. It is possible that additional cell(s), such as feedthrough buffer (s), maybe placed on the path between the output port OUT of the source end and the input port IN of the destination end.

As shown in FIG. 5, the first power-domain block 302 may include a source end being an always-on block and a destination end being an always-on block or a power-switchable block. Hence, there may not be special cell electrically cascaded to any of the output port OUT of the source end and the input port IN of the destination end.

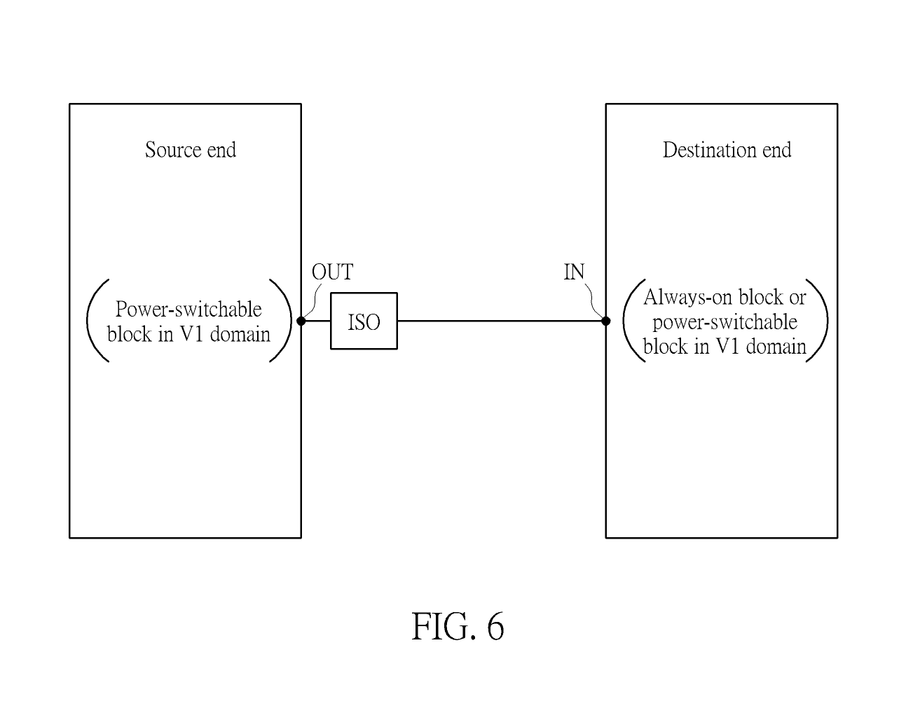

As shown in FIG. 6, the first power-domain block 302 may include a source end being a power-switchable block and a destination end being an always-on block or a power-switchable block. Hence, the integrated circuit 100 may further include an isolation cell ISO formed on the semiconductor layer 102 and electrically cascaded to the output port OUT of the source end. There may not be special cell electrically cascaded to the input port IN of the destination end.

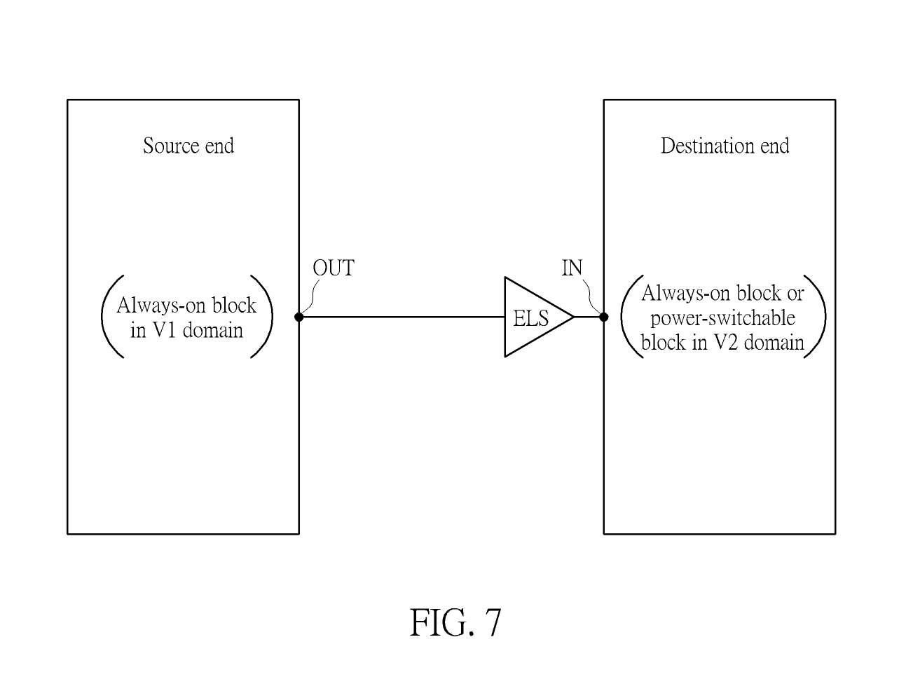

As shown in FIG. 7, the first power-domain block 302 may include a source end being an always-on block, and the second power-domain block 304 may include a destination end being an always-on block or a power-switchable block. Hence, the integrated circuit 100 may further include an enable level shifter ELS formed on the semiconductor layer 102 and electrically cascaded to the input port IN of the destination end. There may not be special cell electrically cascaded to the output port OUT of the source end.

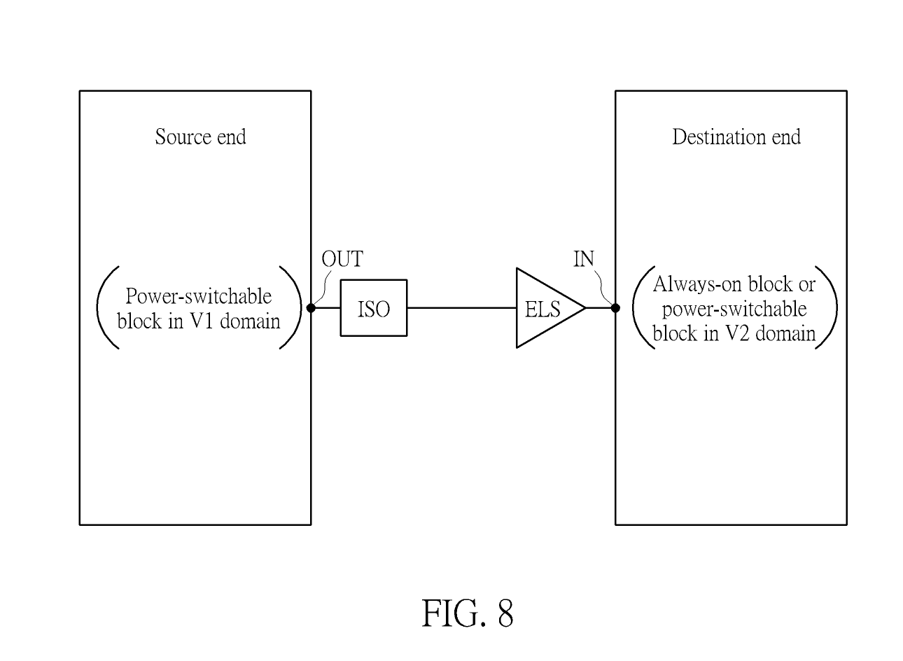

As shown in FIG. 8, the first power-domain block 302 may include a source end being a power-switchable block, and the second power-domain block 304 may include a destination end being an always-on block or a power-switchable block. Hence, the integrated circuit 100 may further include an enable level shifter ELS and an isolation cell ISO formed on the semiconductor layer 102, where the isolation cell ISO may be electrically cascaded to the output port OUT of the source end, and the enable level shifter ELS may be electrically cascaded to the input port IN of the destination end.

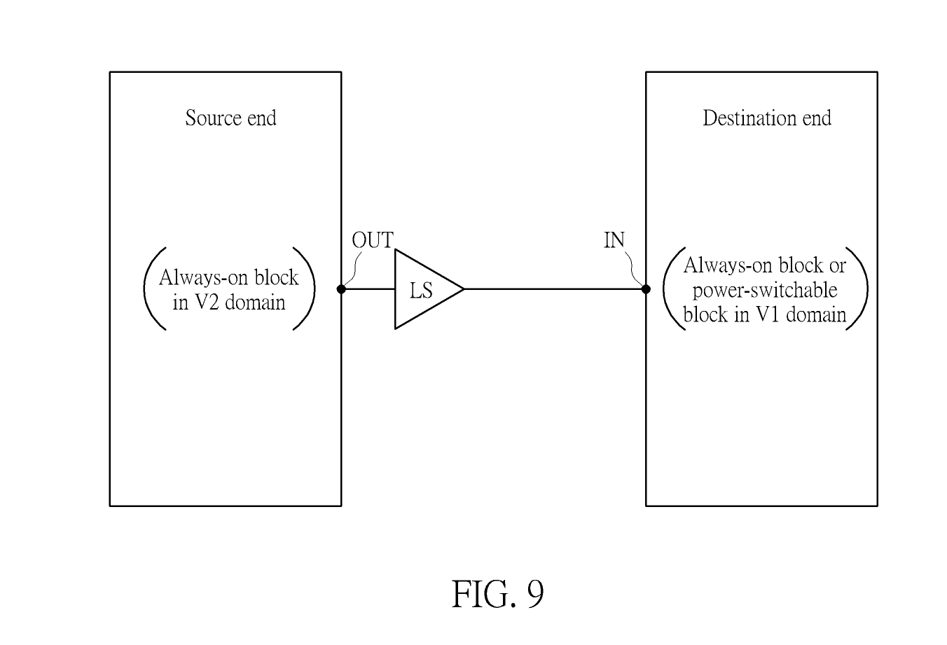

As shown in FIG. 9, the second power-domain block 304 may include a source end being an always-on block, and the first power-domain block 302 may include a destination end being an always-on block or a power-switchable block. Hence, the integrated circuit 100 may further include a level shifter LS formed on the semiconductor layer 102 and electrically cascaded to the output port OUT of the source end. There may not be special cell electrically cascaded to the input port IN of the destination end.

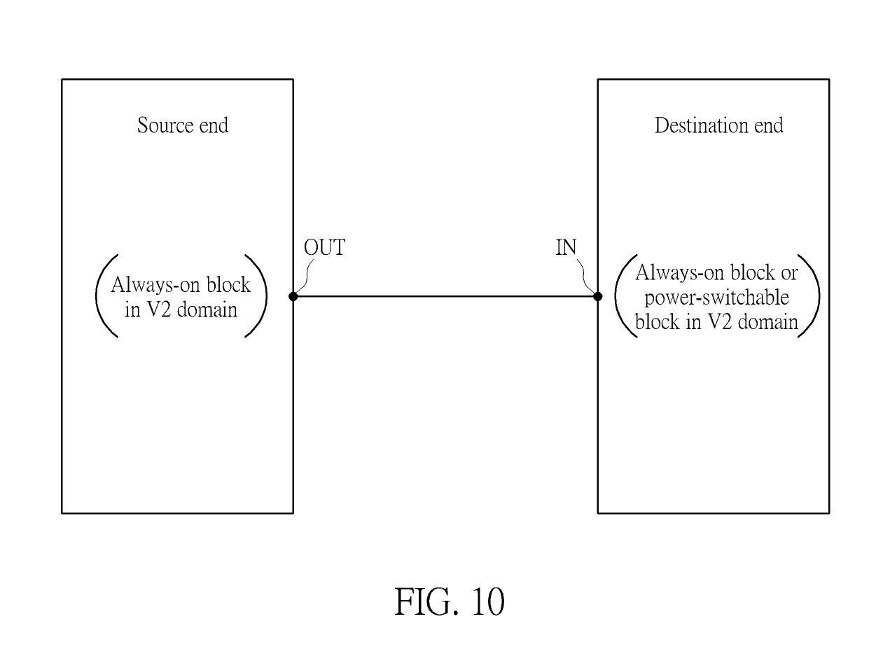

As shown in FIG. 10, the second power-domain block 304 may include a source end being an always-on block and a destination end being an always-on block or a power-switchable block. Ina case where the feedthrough buffer between the source end and the destination end is required to be active under the standby/suspend/power-saving mode, there may not be special cell electrically cascaded to any of the output port OUT of the source end and the input port IN of the destination end.

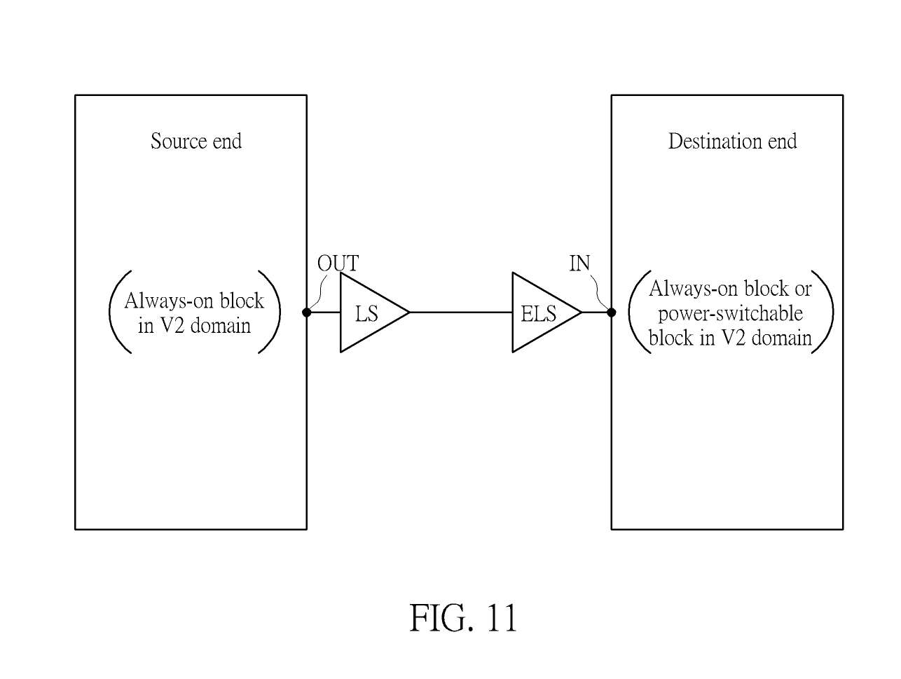

As shown in FIG. 11, the second power-domain block 304 may include a source end being an always-on block and a destination end being an always-on block or a power-switchable block. Ina case where the feedthrough buffer between the source end and the destination end is not required to be active under the standby/suspend/power-saving mode, the integrated circuit 100 may further include a level shifter LS and an enable level shifter ELS formed on the semiconductor layer 102, where the level shifter LS may be electrically cascaded to the output port OUT of the source end, and the enable level shifter ELS may be electrically cascaded to the input port IN of the destination end. It should be noted that the feedthrough buffer (not shown) between the source end and the destination maybe allocated in the V1 power domain for power saving, since the first power source V1 may be shut off when a standby/suspend/power-saving mode is enabled.

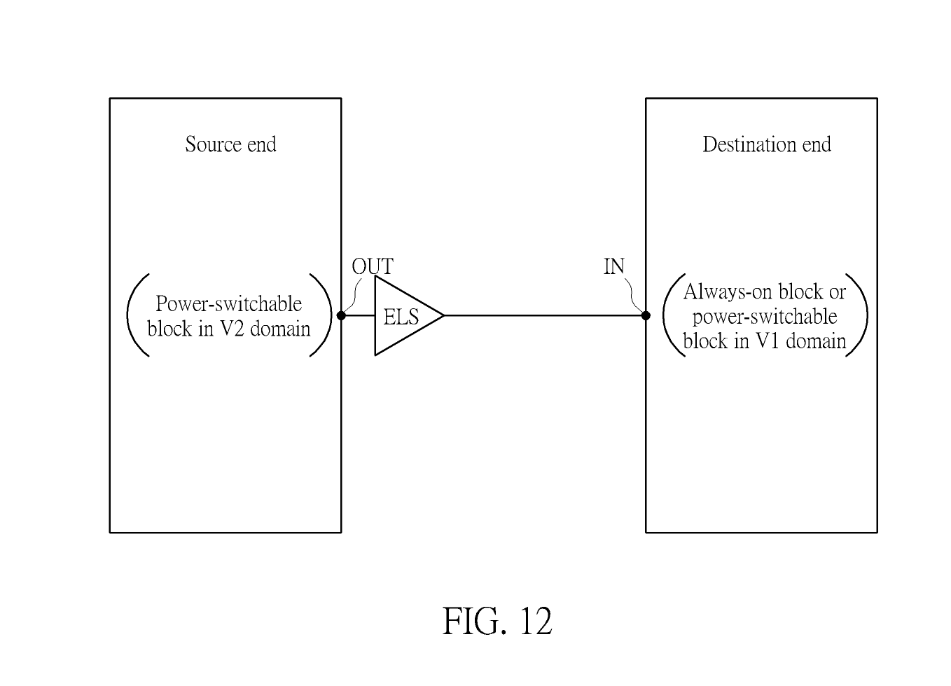

As shown in FIG. 12, the second power-domain block 304 may include a source end being a power-switchable block, and the first power-domain block 302 may include a destination end being an always-on block or a power-switchable block. Hence, the integrated circuit 100 may further include an enable level shifter ELS formed on the semiconductor layer 102 and electrically cascaded to the output port OUT of the source end. There may not be special cell electrically cascaded to the input port IN of the destination end.

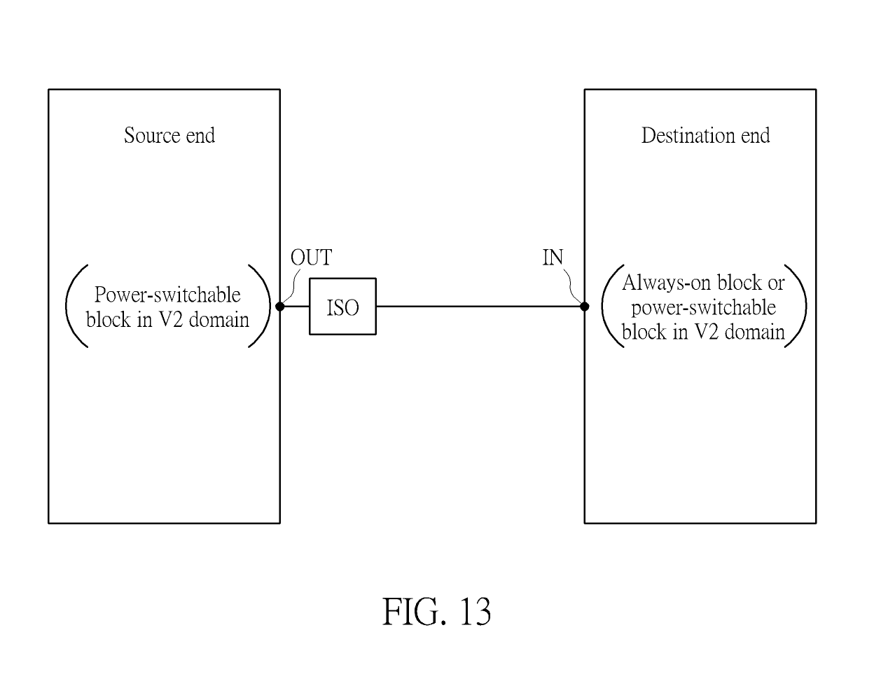

As shown in FIG. 13, the second power-domain block 304 may include a source end being a power-switchable block and a destination end being an always-on block or a power-switchable block. In a case where the feedthrough buffer between the source end and the destination end is required to be active under the standby/suspend/power-saving mode, the integrated circuit 100 may further include an isolation cell ISO formed on the semiconductor layer 102 and electrically cascaded to the output port OUT of the source end. There may not be special cell electrically cascaded to the input port IN of the destination end.

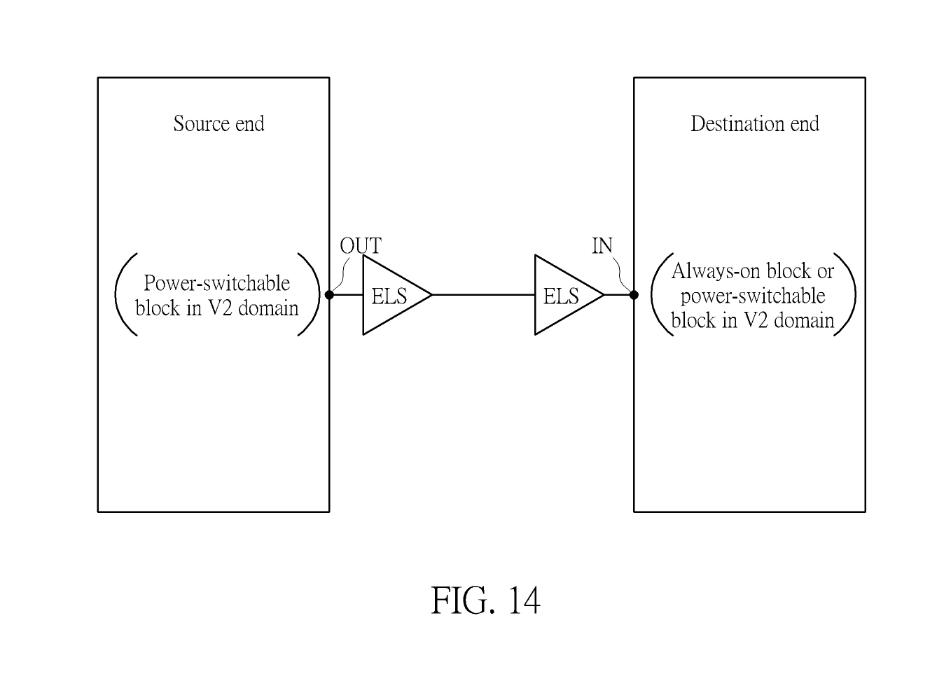

As shown in FIG. 14, the second power-domain block 304 may include a source end being a power-switchable block and a destination end being an always-on block or a power-switchable block. In a case where the feedthrough buffer between the source end and the destination end is not required to be active under the standby/suspend/power-saving mode, the integrated circuit 100 may further include two enable level shifters ELS formed on the semiconductor layer 102, where one enable level shifter ELS may be electrically cascaded to the output port OUT of the source end, and the other enable level shifter ELS may be electrically cascaded to the input port IN of the destination end. It should be noted that the feedthrough buffer (not shown) between the source end and the destination may be allocated in the V1 power domain for power saving, since the first power source V1 may be shut off when a standby/suspend/power-saving mode is enabled.

As mentioned above, based on the first power source design of the present invention, the first power source V1 and the second power source V2 maybe derived from external power sources of the integrated circuit 100, respectively. In an alternative design, at least one of the first power source V1 and the second power source V2 may be obtained/generated inside the integrated circuit 100. Specifically, in a case where second power source design proposed by the present invention is employed, the first power source V1 and the second power source V2 may be both derived from the same external power source of the integrated circuit 100.

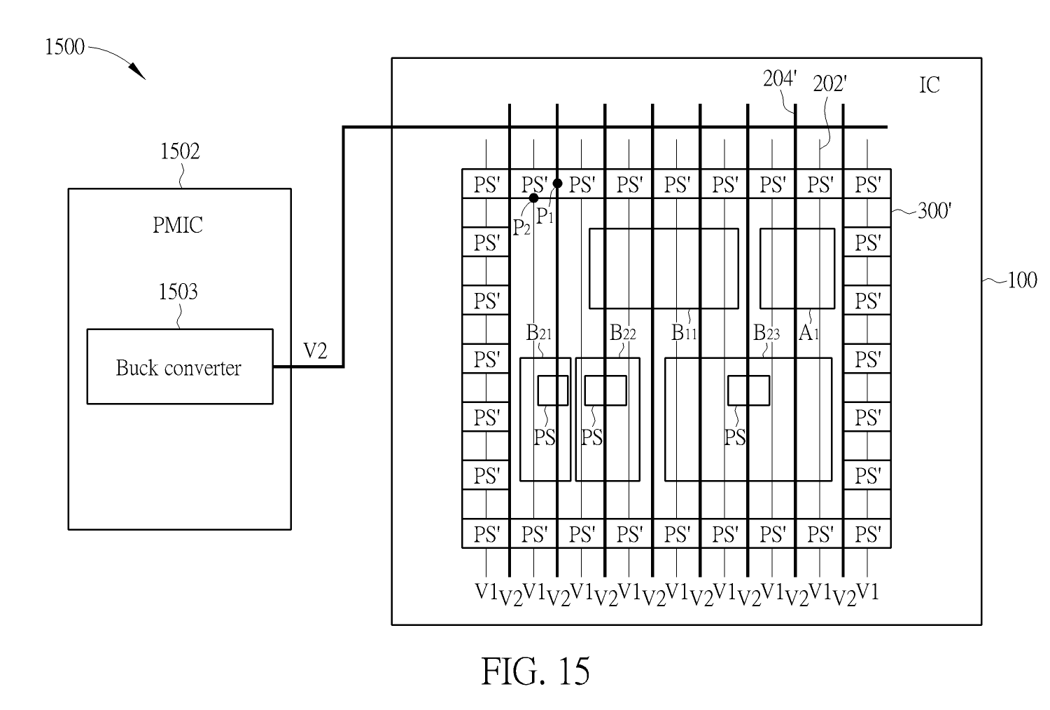

Please refer to FIG. 15, which is a diagram illustrating a system using a single-bulk solution according to an embodiment of the present invention. By way of example, but not limitation, the system 1500 may be a mobile phone chipset. As shown in FIG. 15, the system 1500 may include a power management integrated circuit (PMIC) 1502 and the aforementioned integrated circuit (IC) 100. For clarity and simplicity, only one specific functional circuit block 300′ of the functional circuit blocks 103 in the integrated circuit 100 is shown in FIG. 15. For example, the specific functional circuit block 300′ may be a modem subsystem. The PMIC 1502 may have a single buck converter for generating one supply voltage. In this example, the PMIC 1502 has a buck converter 1503 acting as an external power source of the integrated circuit 100. It should be noted that the first power source V1 and the second power source V2 in the integrated circuit 100 may be derived from the same buck converter 1503. In this embodiment, the specific functional circuit block 300′ may include a plurality of power switches PS′ each having an input port P₁ coupled to the same external power source (i.e., the buck converter 1503) and an output port P₂ coupled to one of first power trunks 202′. The power switches PS′ maybe particularly designed to serve as the first power source V1 (which may be generated based on the second power source V2).

As shown in FIG. 15, the specific functional circuit block 300′ may include an always-on block A₁ in the first power domain that uses the first power source V1, and may further include an always-on block B₁₁ and power-switchable blocks B₂₁, B₂₂, B₂₃ in the second power domain that uses the second power source V2. The first power source V1 and the second power source V2 can be of the same voltage or different voltages. For example, the always-on block A₁ may have glue logics and/or feedthrough buffers. The always-on block A₁ may have no power switch PS included therein, and may be coupled to at least one of first power trunks 202′. Hence, the always-on block A₁ maybe directly powered by the first power source V1. Regarding the always-on block B₁₁, it may have no power switch PS included therein, and may be coupled to at least one of second power trunks 204′. Hence, the always-on block B₁₁ may be directly powered by the second power source V2. Each of the power-switchable blocks B₂₁, B₂₂ and B₃₂ may have a power switch PS included therein, and the power switch PS may be coupled to one of second power trunks 204′. Hence, each of the power-switchable blocks B₂₁, B₂₂ and B₂₃ may be powered by the second power source V2 when the associated power switch PS is switched on, and may be disconnected from the second power source V2 when the associated power switch PS is switched off.

In this embodiment, when the system 1500 enters a standby/suspend/power-saving mode, the external power source (i.e., the buck converter 1503) may not be shut off, and part or all of the power-switchable blocks B₂₁, B₂₂ and B₂₃ may have internal circuit components powered off by controlling associated power switches PS. Though the power switches PS cannot be powered off, the integrated circuit 100 still gains the benefits/advantages from the proposed multi-source power domain architecture. The power switches PS′ may be arranged in at least one edge of the specific functional circuit block 300′. By way of example, the power switches PS′ maybe arranged in a ring around the specific functional circuit block 300′, as shown in FIG. 15. Hence, one objective of having power trunks of multiple power sources distributed in a power mesh area corresponding to a specific functional circuit block is achieved. In this way, the placement of circuit components belonging to different power domains is more flexible when compared to the conventional design, which may lead to a reduced number of feedthrough buffers needed. In addition, certain feedthrough buffers may be powered by a power source that can be shut down. This may further reduce the leakage for power saving when the feedthrough buffers are powered off by the shut-down power source. Moreover, compared to the multi-bulk solution, the single-bulk solution can reduce the production cost due to only one buck converter needed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit, comprising:
a semiconductor layer;
at least one metal layer;
a plurality of functional circuit blocks, formed on the semiconductor layer; and
a power mesh, formed on the at least one metal layer, wherein the power mesh has a specific area corresponding to a specific functional circuit block of the functional circuit blocks, the specific area at least has a first power trunk of a first power source and a second power trunk of a second power source distributed therein.

2. The integrated circuit of claim 1, wherein the specific functional circuit block comprises:
a first power-domain block, coupled to the first power trunk; and
a second power-domain block, coupled to the second power trunk.

3. The integrated circuit of claim. 2, wherein the first power-domain block includes at least one always-on block with no power switch.

4. The integrated circuit of claim. 2, wherein the first power-domain block includes at least one power-switchable block with a power switch.

5. The integrated circuit of claim 2, wherein the second power-domain block includes at least one always-on block with no power switch.

6. The integrated circuit of claim 2, wherein the second power-domain block includes at least one power-switchable block with a power switch.

7. The integrated circuit of claim. 2, wherein the first power-domain block includes a source end being a power-switchable block and a destination end being an always-on block or a power-switchable block;
and the integrated circuit further comprises an isolation cell formed on the semiconductor layer and electrically cascaded to an output port of the source end.

8. The integrated circuit of claim. 2, wherein the first power-domain block includes a source end being an always-on block, the second power-domain block includes a destination end being an always-on block or a power-switchable block, and the integrated circuit further comprises an enable level shifter formed on the semiconductor layer and electrically cascaded to an input port of the destination end.

9. The integrated circuit of claim. 2, wherein the first power-domain block includes a source end being a power-switchable block, the second power-domain block includes a destination end being an always-on block or a power-switchable block, the integrated circuit further comprises an enable level shifter and an isolation cell formed on the semiconductor layer, the isolation cell is electrically cascaded to an output port of the source end, and the enable level shifter is electrically cascaded to an input port of the destination end.

10. The integrated circuit of claim 2, wherein the second power-domain block includes a source end being an always-on block, the first power-domain block includes a destination end being an always-on block or a power-switchable block, and the integrated circuit further comprises a level shifter formed on the semiconductor layer and electrically cascaded to an output port of the source end.

11. The integrated circuit of claim 2, wherein the second power-domain block includes a source end being an always-on block and a destination end being an always-on block or a power-switchable block; the integrated circuit further comprises a level shifter and an enable level shifter formed on the semiconductor layer; the level shifter is electrically cascaded to an output port of the source end; and the enable level shifter is electrically cascaded to an input port of the destination end.

12. The integrated circuit of claim 2, wherein the second power-domain block includes a source end being a power-switchable block, the first power-domain block includes a destination end being an always-on block or a power-switchable block, and the integrated circuit further comprises an enable level shifter formed on the semiconductor layer and electrically cascaded to an output port of the source end.

13. The integrated circuit of claim 2, wherein the second power-domain block includes a source end being a power-switchable block and a destination end being an always-on block or a power-switchable block; and the integrated circuit further comprises an isolation cell formed on the semiconductor layer and electrically cascaded to an output port of the source end.

14. The integrated circuit of claim 2, wherein the second power-domain block includes a source end being a power-switchable block and a destination end being an always-on block or a power-switchable block; the integrated circuit further comprises a first enable level shifter and a second enable level shifter formed on the semiconductor layer; the first enable level shifter is electrically cascaded to an output port of the source end; and the second enable level shifter is electrically cascaded to an input port of the destination end.

15. The integrated circuit of claim 1, wherein the first power source and the second power source are derived from external power sources of the integrated circuit, respectively.

16. The integrated circuit of claim 15, wherein when the integrated circuit enters a suspend mode, the first power source is shut off and the second power source remains active.

17. The integrated circuit of claim 1, wherein the first power source and the second power source are both derived from a same external power source of the integrated circuit.

18. The integrated circuit of claim 17, wherein the specific functional circuit block includes a plurality of power switches each having an input port coupled to the same external power source and an output port coupled to the first power trunk; and the power switches serve as the first power source.

19. The integrated circuit of claim 18, wherein the power switches are arranged in at least one edge of the specific functional circuit block.

20. The integrated circuit of claim 1, wherein the specific area has first power trunks of the first power source and second power trunks of the second power source that are arranged in an interleaving fashion.

21. A system with power management, comprising:
a first integrated circuit, comprising at least a first power source and a second power source; and
a second integrated circuit, externally coupled to the first integrated circuit, the second integrated circuit comprising at least one functional circuit block, wherein the functional circuit block has at least one first power-domain block powered by the first power source and at least one second power-domain block powered by the second power source;
wherein the first integrated circuit enables both of the first power source and the second power source when the second integrated circuit is in a normal mode, and disables the first power source and enables the second power source when the second integrated circuit is in a suspend mode.

22. The system of claim 21, wherein the first power-domain block includes at least one power-switchable block with a power switch.
